(19) United States
(12) Patent Application Publication
(10) Pub. No.: US 2008/0009086 A1
(43) Pub. Date: Jan. 10, 2008

(54) METHOD OF PACKAGING LIGHT EMITTING DIODES

(76) Inventors: Anthony Joseph Whitehead, Hsin-Chu City (TW); Ta-Shuang Kuan, Hsin-Chu Hsien (TW); Chia-Tsung Chan, Tao-Yuan Hsien (TW); Chia-Te Lin, Chia-Yi Hsien (TW)

Correspondence Address: NORTH AMERICA INTELLECTUAL PROPERTY CORPORATION, P.O. BOX 506, MERRIFIELD, VA, 22116, US

(21) Appl. No.: 11/456,208

(22) Filed: Jul. 9, 2006

(51) Int. Cl. H01L 21/00

(52) U.S. Cl. 438/26

(57) ABSTRACT

A method of packaging light emitting diodes includes providing a wafer having a plurality of LEDs thereon, forming at least a sealant surrounding the LEDs, providing a glass substrate to cover the LEDs, the sealant, and the wafer, providing a UV hardening process to harden the sealant, forming a polarization film on the glass substrate, and dicing the wafer.

### BACKGROUND OF INVENTION

1. Field of the Invention

The invention relates to a method of packaging light emitting diodes (LEDs), and more particularly, to a method of packaging LEDs that generate polarizing lights.

2. Description of the Prior Art

Since the LED has the advantages of a long lifetime, a small size, a high resistance to earthquakes, and a low consumption of electric power, the LED is widely applied as a pilot lamp or a light source for various household appliances and instruments. Additionally, the LED has been developed toward producing colorful lights and high brightness in recent years, so that the LED is further applied in large-sized display signboards and traffic lights, and may substitute for tungsten lamps and mercury lamps to become a stream of illumination light sources with low power consumption and low contamination in the future.

The traditional method of packaging semiconductor devices including LEDs comprises a lead type packaging method and a chip type packaging method. The lead type LED elements usually serve as pilot devices of various circuits or electronic instruments. FIG. 1 is a schematic diagram of a lead type LED element 10 according to the prior art. The lead type LED element 10 comprises a LED 12, a cup shape carrier 14, a leading wire 16, and a side leading wire 18. According to a packaging process, the LED 12 is set to the hollow of the cup shape carrier 14, and the cup shape carrier 14 is then filled up with a seal material 22 that can fix the LED 12 on the cup shape carrier 14. Next, an N type electrode and a P type electrode (not shown) of the LED 12 are connected to the leading wire 16 and the side leading wire 18 through wires, respectively. Finally, a protecting unit 20 is used to cover the LED 12 and a portion of the leading wire 16 and the side leading wire 18.

Please refer to FIG. 2. FIG. 2 is a schematic diagram of the chip type LED element 30 according to the prior art. The prior art chip type LED element 30 comprises a base seat 32 having two electrodes 40, 42, and a LED 34 having an N type electrode 36 and a P type electrode 38 corresponding with the electrodes 40 and 42 respectively. In the process of fabricating the chip type LED element 30, the LED 34 is glued on the base seat 32 with a silver glue (not shown). Then, a wire bonding process is performed to connect the N type electrode 36 and the P type electrode 38 of the LED 34 to the electrodes 40, 42 of the base seat 32 through two conductive wires 44, 46 individually. After the wire bonding process, a sealing process is performed by setting the whole LED element 30 in a mold (not shown), filling up the mold with epoxy resin or other similar materials, and taking the LED element 30 out of the mold after it hardens. Finally, the LEDs 34, the base seat 32, and all the electrodes and wires are covered in a plastic mold 48 that is composed of epoxy resin.

Generally, LEDs are applied in LCD displays, projectors, and pilot lamps. The light sources of those appliances have to be polarized lights. Therefore, when a conventional LED is used to serve as a light source of the appliance, a polarization film has to be formed on the LED, or a polarization layer has to be formed on the surface of the LED after it is packaged for satisfying the standards of the light sources for those appliances.

### SUMMARY OF INVENTION

It is therefore an objective of the claimed invention to provide a method of packaging LEDs utilizing methods of packaging a liquid crystal on silicon (LCOS) displays or a contact image sensor (CIS) that can package the polarization layer together with LED elements to solve the above-mentioned problem, making another polarization film on LED appliances of the prior art.

According to the claimed invention, the method of packaging light emitting diodes (LEDs) comprises providing a wafer having a plurality of LEDs thereon and forming at least a sealant surrounding the LEDs on the wafer. Then a glass substrate is provided for covering the LEDs, the sealant, and the wafer, and the sealant is exposed under an ultraviolet (UV) light to perform an ultraviolet curing process for hardening the sealant. Then, a polarization layer is formed on the glass substrate. Finally, the glass substrate and the wafer are diced to separate the LEDs and finish the process of packaging LEDs.

The present invention utilizes methods of packaging LCOS or CIS to form LEDs on the semiconductor wafer directly and cover the LEDs by a glass substrate to form protection. Therefore the present invention does not need to utilize epoxy resin material to form the protection on the surface of the LEDs, and also does not need a cup shape carrier to separate each LED according to the method of packaging LEDs according to the prior art. Furthermore, according to the present invention, a polarization layer is formed on the surface of the glass substrate before packaging LEDs. As a result, the LED element serving as a light source in each appliance does not require another polarization board to be made after packaging. This effectively simplifies the process of fabricating LEDs for use as a light source in the appliances.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 is a schematic diagram of a lead type LED element according to the prior art.

FIG. 2 is a schematic diagram of a chip type LED element according to the prior art.

FIG. 3 to FIG. 6 are schematic diagrams of a method of packaging LEDs according to the present invention.

FIG. 7 is a schematic diagram of another embodiment of a method of packaging LEDs according to the present invention.

FIG. 8 is a flow chart of a method of packaging LEDs according to the present invention.

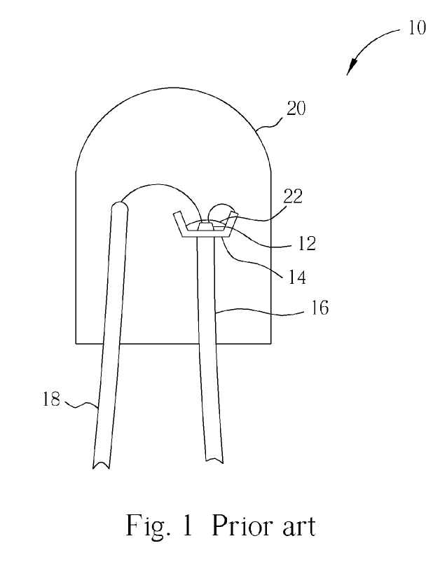

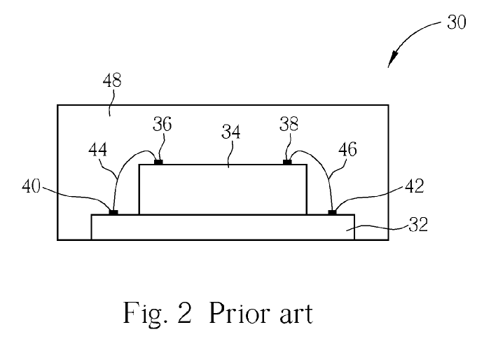

### DETAILED DESCRIPTION

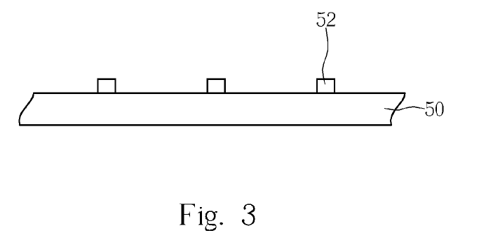

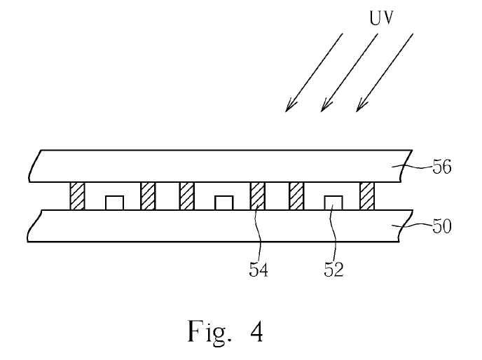

Please refer to FIG. 3 to FIG. 6, which are schematic diagrams of a method of packaging LEDs according to the present invention. As shown in FIG. 3, a plurality of LEDs 52 and corresponding wires are formed on a surface of the substrate 50 that is a semiconductor wafer, a glass substrate, or a quartz substrate. And referring to FIG. 4, a plurality of sealants 54, having individual seal pattern, are formed on the surface of the substrate 50 to surround the LEDs 52, respectively. Then, a transparent substrate 56, a glass substrate or a quartz substrate used for packaging LCOS is laminated on the substrate 50 and covers the LEDs 52 and the sealant 54 to perform a lamination process. The sealant 54 is then exposed under an ultraviolet (UV) light for hardening the sealant 54, so that the transparent substrate 56 is fixed on the substrate 50.

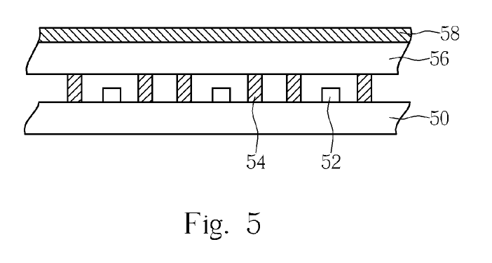

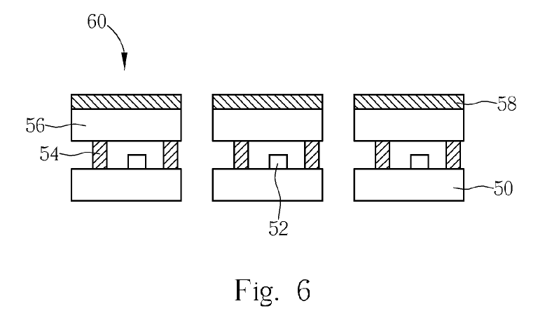

Please refer to FIG. 5, a polarization layer 58 is formed on the surface of a transparent substrate 56 by a deposition method, or a polarization film is glued on the transparent substrate 56 to form the polarization layer 58. As shown in FIG. 6, the substrate 50, the transparent substrate 56, and the polarization layer 58 are cut together along the seal patterns of the sealants surrounding each of the LEDs 52 to separate each LED 52 so as to form a plurality of LED dies and finish the process of packaging the LEDs.

In the present embodiment, the LEDs 52 are discretely set on the surface of the substrate 50. And each of the sealants 54 surrounds each of the LEDs 52, so a diced LED die 60 only comprises a single LED 52. And the diced LED die 60 can be directly set in various circuits or electronic instruments such as pilot lamps, just like the conventional lead type LEDs.

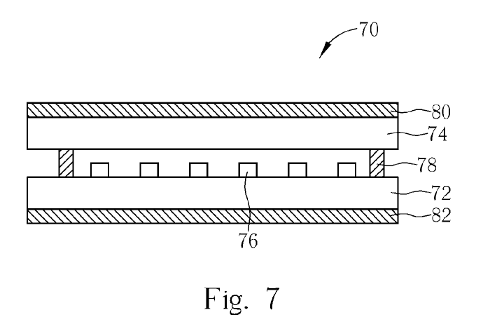

Please refer to FIG. 7. FIG. 7 is a schematic diagram of another embodiment according to the present invention. In the present embodiment, a diced LED element 70 comprises a quartz substrate 72, a glass substrate 74 opposite to the quartz substrate 72, a plurality of LEDs 76 and corresponding wires positioned on the surface of the quartz substrate 72, and a sealant 78 surrounding the LEDs 76, which fix the glass substrate 74 on the quartz substrate 72. The LED element 70 further comprises a polarization layer 80 set on the surface of the glass substrate 74. It should be noted that the LED element 70 comprises a plurality of LEDs 76 that are arranged in an array. Therefore, the LED element 70 can be directly applied to an appliance, such as a LCD, that needs a planar light source. On the other hand, the quartz substrate 72 has a characteristic of being pervious to light, so that the present invention comprises forming a polarization layer 82 on the surface of the quartz substrate 72 before cutting the glass substrate 74 and the quartz substrate 72, and cutting the polarization layer 82 together with the quartz substrate 72. As a result, the LEDs device 72 can be applied to an appliance which needs a double-sided light source.

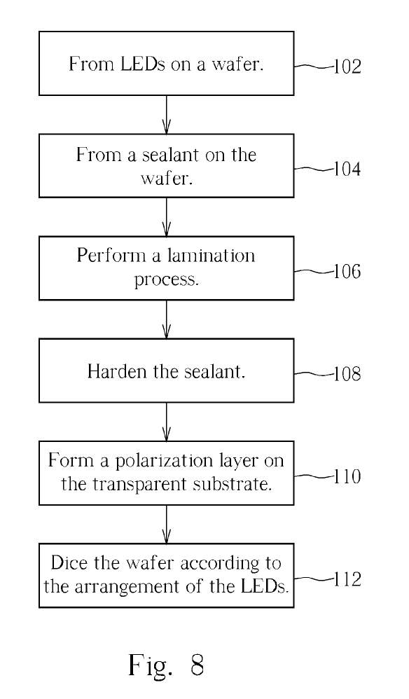

Taken together, please refer to FIG. 8. FIG. 8 is flow chart of the method of packaging LEDs according to the present invention. The present invention comprises the following steps:

Step 102: Provide a wafer and form a plurality of LEDs and corresponding wires on the surface of the wafer.

Step 104: Form at least a sealant on the wafer surface, the sealant having a seal pattern surrounding the LEDs.

Step 106: Perform a lamination process to make a transparent substrate cover the wafer, the LEDs, and the sealant.

Step 108: Expose the sealant under an ultraviolet (UV) light to harden the sealant and fix the transparent substrate on the wafer.

Step 110: Form a polarization layer on the transparent substrate.

Step 112: Dice the wafer along the seal pattern of the sealant that surrounds each of the LEDs so as to form a plurality of LED dies.

In contrast to the prior art, the present invention utilizes packaging technology of LCOS or CIS to perform the method of packaging LEDs. The present invention utilizes a glass to cover the LEDs, and to set a space for setting the LEDs with a wafer and sealant that does not need to form the base seats or plastic molds of the prior art surrounding the LEDs. So the LED packaging technology of the present invention represents breakthrough advancement. In addition, according to the present invention, a polarization layer is optically formed on the surface of the transparent substrate, and the polarization layer is cut together with LEDs to make the LEDs device produce polarized lights after packaging. This LED meets the demands of polarizing light sources of general appliances. As a result, the packaged LED elements can be directly set on each appliance according to the present invention and further simplify assembly and the manufacturing process, along with lowering the manufacturing cost of each appliance.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of packaging light emitting diodes (LEDs) comprising:
providing a wafer having a plurality of LEDs thereon;
forming at least a sealant surrounding the LEDs on the wafer;
providing a glass substrate to cover the LEDs, the sealant, and the wafer;
exposing the sealant under an ultraviolet (UV) light;
forming a polarization layer on the glass substrate; and
dicing the wafer to separate the LEDs.

2. The method of claim 1, wherein the step of forming the polarization layer comprises depositing the polarization layer on the glass substrate.

3. The method of claim 1, wherein the step of forming the polarization layer comprises stamping a polarization film on the glass substrate.

4. The method of claim 1, wherein the step of dicing the wafer comprises cutting the polarization layer together with the wafer and the glass substrate.

5. The method of claim 1, wherein the UV light is used for hardening the sealant to fix the glass substrate on the wafer.

6. The method of claim 1, wherein the LEDs are arranged in an array on the wafer.

7. The method of claim 1, wherein the LEDs are arranged discretely on the wafer.

8. The method of claim 7 comprising forming a plurality of sealants surrounding each of the LEDs.

9. The method of claim 8, wherein the step of dicing the wafer comprises cutting the wafer along a shape of each of the sealants that surrounds each of the LEDs so as to form a plurality of LED dies.

10. A method of packaging LEDs comprising:
forming a plurality of LEDs on a substrate;
forming at least a sealant on the substrate, the sealant having a seal pattern surrounding the LEDs;
performing a lamination process to make a transparent substrate cover the substrate, the LEDs, and the seal;
hardening the sealant to fix the transparent substrate to the substrate; and
dicing the transparent substrate and the substrate to separate the LEDs.

11. The method of claim 10 further comprising a step of forming a polarization layer on the transparent substrate after hardening the sealant.

12. The method of claim 11, wherein the polarization layer is formed through a deposition process.

13. The method of claim 11, wherein the polarization layer is formed through stamping a polarization film on the transparent substrate.

14. The method of claim 11, wherein the step of dicing the substrate comprises cutting the polarization layer together with the substrate and the transparent substrate.

15. The method of claim 10, wherein the substrate is a glass substrate, a quartz substrate, or a wafer, and the transparent substrate is a glass substrate or a quartz substrate.

16. The method of claim 15 further comprising a step of forming a first polarization layer on the transparent substrate and a second polarization layer on the substrate after hardening the sealant.

17. The method of claim 16, wherein the first and the second polarization layers are formed through a deposition process or through stamping polarization films on the transparent substrate and the substrate respectively.

18. The method of claim 10, wherein the LEDs are arranged in an array on the substrate.

19. The method of claim 10, wherein the LEDs are arranged discretely on the substrate.

20. The method of claim 10, wherein the step of hardening the sealant comprises performing an ultraviolet hardening process.

21. The method of claim 10, wherein the step of dicing the substrate comprises cutting the substrate and the transparent substrate along the seal pattern that surrounds the LEDs so as to form a plurality of LED dies.
